(19) United States
(12) Patent Application Publication
(10) Pub. No.: US 2026/0334150 A1
(43) Pub. Date: Oct. 22, 2026

(54) MANUFACTURING APPARATUS AND MANUFACTURING METHOD OF SEMICONDUCTOR DEVICE

(71) Applicant: SHINKAWA LTD., Tokyo (JP)

(72) Inventors: Yuji Eguchi, Tokyo (JP); Kohei Seyama, Tokyo (JP)

(73) Assignee: SHINKAWA LTD., Tokyo (JP)

(21) Appl. No.: 19/529,005

(22) Filed: Feb. 3, 2026

Related U.S. Application Data
(62) Division of application No. 17/608,753, filed on Apr. 23, 2021, now abandoned.

(30) Foreign Application Priority Data
May 26, 2020 (JP) 2020-091570

(51) Int. Cl. H10P 72/50; H10P 72/00; H10P 72/78

(52) U.S. Cl. CPC H10P 72/50; H10P 72/78; H10P 72/0606

(57) ABSTRACT

A manufacturing apparatus of a semiconductor device includes a stage (12), a bonding head (14), a copying mechanism (22) mounted on the bonding head (14), and a controller (34) executing adjustment processing. In the adjustment processing, the controller (34) causes a facing surface (50) of the bonding head (14) to abut against a reference surface (110) of the stage (12) after setting the copying mechanism (22) to the locked state, then presses the facing surface (50) against the reference surface (110) after switching the copying mechanism (22) to a free state, and after that, switches the copying mechanism (22) to the locked state.

### CROSS-REFERENCE TO RELATED APPLICATION

This is a divisional application of patent application Ser. No. 17/608,753, filed on Nov. 3, 2021, which is a 371 application of the International PCT application serial no. PCT/JP2021/016472, filed on Apr. 23, 2021, which claims the priority benefit of Japan Patent Application No. 2020-091570, filed on May 26, 2020. The entirety of each of the above-mentioned patent applications is hereby incorporated by reference herein and made a part of this specification.

### TECHNICAL FIELD

The present specification discloses a manufacturing apparatus and a manufacturing method of a semiconductor device, in which a stage or a bonding head is equipped with a copying mechanism.

### RELATED ART

Conventionally, there has been widely known a technique for manufacturing a semiconductor device by driving a bonding head while a semiconductor chip is sucked and held by a tip surface (hereinafter referred to as “holding surface”) of the bonding head and bonding the semiconductor chip to a substrate. In such a semiconductor device manufacturing technique, in order to satisfactorily bond the semiconductor chip to a surface of the substrate, it is required that the holding surface be parallel to the plane of the substrate with high accuracy.

There has also been known a manufacturing apparatus in which a stage mounted with a substrate or a bonding head holding a semiconductor chip is equipped with a copying mechanism, in order to make the holding surface parallel to the substrate by a simple procedure. Here, the copying mechanism is a mechanism including a fixed member and a movable member. The fixed member includes one of a concave hemispherical surface and a convex hemispherical surface, the movable member includes the other of the concave hemispherical surface and the convex hemispherical surface, and the movable member is three-dimensionally swingable with respect to the fixed member. The copying mechanism is switchable between a free state in which swinging of the movable member is enabled and a locked state in which swinging of the movable member is restricted.

Patent Document 1 discloses a bonding head equipped with such a copying mechanism. In Patent Document 1, in a state in which the copying mechanism is set to free, by causing a second object held by the bonding head to abut against a first object held on the stage and pressing the second object, an abutting surface of the second object is adjusted to be parallel to a surface of the first object.

### PRIOR ART DOCUMENTS

### Patent Documents

Patent Document 1: Japanese Patent No. 3919684

### SUMMARY OF THE INVENTION

### Problems to Be Solved by the Invention

According to the technique of Patent Document 1, the holding surface of the bonding head can be made parallel to the stage to some extent by a simple procedure. However, in a case where the holding surface of the bonding head or the second object held by the bonding head is simply pressed against the stage or the first object held by the stage, due to the influence of friction or the like, sometimes the holding surface is not completely parallel to a mounting surface. That is, in the conventional technique, it is difficult to adjust the holding surface of the bonding head to be parallel to the mounting surface of the stage with high accuracy.

Therefore, the present specification discloses a manufacturing apparatus and a manufacturing method of a semiconductor device, in which the holding surface of the bonding head can be adjusted by a simple procedure to be parallel to the mounting surface of the stage with high accuracy.

### Means for Solving the Problems

A manufacturing apparatus of a semiconductor device disclosed in the present specification is characterized by including: a stage, having a mounting surface on which a substrate is mounted; a bonding head, having a holding surface sucking and holding a chip, movable relative to the stage in a plane direction and a normal direction of the stage; a copying mechanism, having a first spherical surface and a second spherical surface provided swingably with respect to the first spherical surface, mounted on the stage or the bonding head, in which the copying mechanism causes a facing surface being the mounting surface or the holding surface and connected to the second spherical surface to swing with respect to a reference surface facing the facing surface and being the holding surface or the mounting surface, and is switchable between a free state in which swinging of the facing surface is enabled and a locked state in which swinging of the facing surface is restricted; and a controller, executing adjustment processing once or more times and adjusting the facing surface to be parallel to the reference surface, in which in the adjustment processing, the facing surface is caused to directly or indirectly abut against the reference surface after the copying mechanism is set to the locked state, then the copying mechanism is switched to the free state and the facing surface is directly or indirectly pressed against the reference surface, and then the copying mechanism is switched to the locked state.

In this case, the controller may repeat the adjustment processing until a pressing position being an axial position of the bonding head when the facing surface is pressed against the reference surface in the adjustment processing reaches a specified reference value.

The controller may store the axial position of the bonding head when the facing surface is pressed against the reference surface as the pressing position. The controller may repeat the adjustment processing until a change amount between the pressing position obtained by a previous pressing and the pressing position obtained by a current pressing reaches a specified reference value.

The copying mechanism may be mounted on the stage. In the adjustment processing, the controller may press the holding surface being the reference surface against an intersection of the mounting surface being the facing surface and a normal of the mounting surface passing through a swing center of the copying mechanism.

The controller may also execute initial processing prior to the adjustment processing. In the initial processing, the controller may cause the facing surface to directly or indirectly abut against the reference surface after setting the copying mechanism to the free state, then directly or indirectly press the facing surface against the reference surface, and then switch the copying mechanism to the locked state.

A manufacturing method of a semiconductor device disclosed in the present specification is a manufacturing method of a semiconductor device as follows. By bonding a chip sucked and held by a holding surface of a bonding head having a copying mechanism to a substrate mounted on a stage, a semiconductor device is manufactured. The manufacturing method of a semiconductor device is characterized in the following. The stage or the bonding head is equipped with the copying mechanism. The copying mechanism has a first spherical surface and a second spherical surface provided swingably with respect to the first spherical surface. The copying mechanism causes a facing surface being the mounting surface or the holding surface to swing with respect to a reference surface facing the facing surface and being the holding surface or the mounting surface. The copying mechanism is switchable between a free state in which swinging of the facing surface is enabled and a locked state in which swinging of the facing surface is restricted. An adjustment step is included in which the following operations are performed. The facing surface is caused to directly or indirectly abut against the reference surface after the copying mechanism is set to the locked state, then the copying mechanism is switched to the free state and the facing surface is directly or indirectly pressed against the reference surface, and the copying mechanism is switched to the locked state. The adjustment step is performed once or more times and the facing surface is adjusted to be parallel to the reference surface.

### Effects of the Invention

According to the technique disclosed in the present specification, a holding surface of a bonding head can be adjusted by a simple procedure to be parallel to a mounting surface of a stage with high accuracy.

### BRIEF DESCRIPTION OF THE DRAWINGS

FIG. 1 is a diagram showing a configuration of a manufacturing apparatus of a semiconductor device.

FIG. 2 is a diagram showing an example of a configuration of a copying mechanism.

FIG. 3 is a conceptual diagram showing the principles of copying processing.

FIG. 4A is a conceptual diagram showing a state of copying processing.

FIG. 4B is a conceptual diagram showing a state of copying processing.

FIG. 5A is a conceptual diagram showing a state of copying processing.

FIG. 5B is a conceptual diagram showing a state of copying processing.

FIG. 6A is a conceptual diagram showing a state of copying processing.

FIG. 6B is a conceptual diagram showing a state of copying processing.

FIG. 7 is a flowchart showing a flow of the entire copying processing.

FIG. 8 is a flowchart showing a flow of initial processing.

FIG. 9 is a flowchart showing a flow of adjustment processing.

FIG. 10 is a diagram showing another configuration of a manufacturing apparatus of a semiconductor device.

### DESCRIPTION OF THE EMBODIMENTS

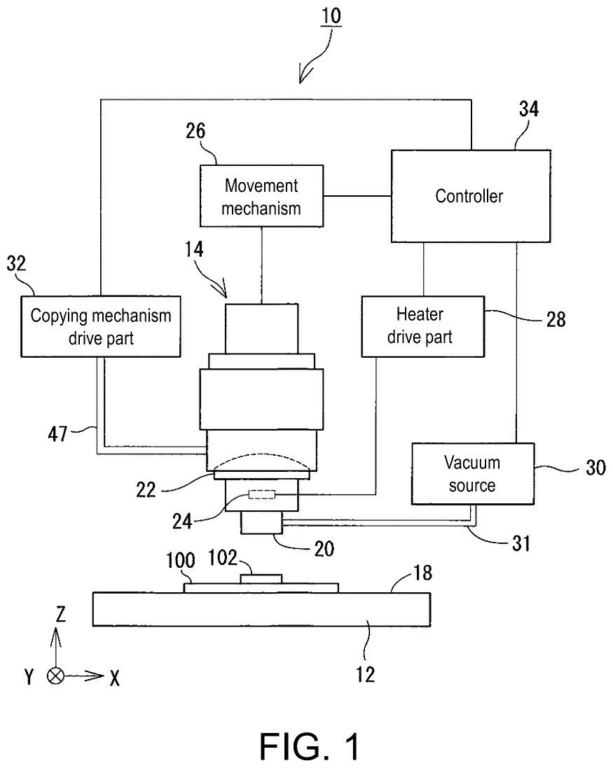

Hereinafter, a configuration of a manufacturing apparatus 10 of a semiconductor device will be described with reference to the drawings. FIG. 1 is a diagram showing a configuration of the manufacturing apparatus 10. As shown in FIG. 1, the manufacturing apparatus 10 includes a stage 12 on which a substrate 100 is mounted, and a bonding head 14 sucking and holding a semiconductor chip 102.

The stage 12 is able to suck and hold the substrate 100, and a heater (not shown) for heating the substrate 100 is mounted inside the stage 12. Heating and suction of the stage 12 are controlled by a controller 34 to be described later. An upper surface of the stage 12 functions as a mounting surface 18 on which the substrate 100 is mounted. The stage 12 of this example is a fixed stage whose vertical and horizontal positions do not change. However, in some cases, the stage 12 may be movable in at least one of the vertical direction and the horizontal direction.

The bonding head 14 is disposed facing the stage 12 and is movable in the horizontal direction and the vertical direction with respect to the stage 12. In order to realize the movement of the bonding head 14, a movement mechanism 26 is provided. The movement mechanism 26 includes, for example, a drive source such as a motor or a hydraulic cylinder, and a linear motion mechanism or a transmission mechanism such as a gear that transmits movement of the drive source to the bonding head 14. Driving of the movement mechanism 26 is controlled by the controller 34.

The bonding head 14 is able to suck and hold the semiconductor chip 102 at a holding surface 20 being a tip surface of the bonding head 14. Hence, a suction hole (not shown) for sucking and holding the semiconductor chip 102 is formed at a tip part of the bonding head 14, and the suction hole is connected to a vacuum source 30 via an air pipe 31. A heater 24 for heating the semiconductor chip 102 being held is built in the tip part of the bonding head 14. The heater 24 is controlled by a heater drive part 28.

After the bonding head 14 has sucked and held the semiconductor chip 102 by the holding surface 20, by mounting the semiconductor chip 102 on a surface of the substrate 100 and performing heating and pressurization thereon, the semiconductor chip 102 is bonded to the substrate 100. Here, in recent years, semiconductor devices have been highly integrated due to the miniaturization of semiconductor processes. In order to enable such high integration, it is necessary to maintain the degree of parallel between the substrate 100 and the semiconductor chip 102 bonded to the substrate 100 with high accuracy. Conventionally, as a means of such parallel adjustment, a manual angle adjustment device called a goniometer stage or a method of adjusting tilting by sandwiching a shim has been proposed. However, such conventional parallel adjustment means require high skill and a large amount of adjustment time.

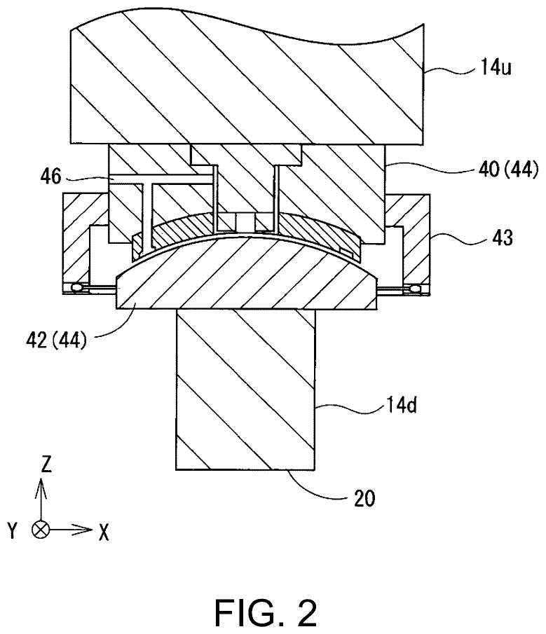

Therefore, the bonding head 14 of this example is equipped with a copying mechanism 22 in order to enable parallel adjustment by a simple procedure. The copying mechanism 22 is a pneumatic device having a spherical aerostatic bearing 44 (see FIG. 2) built therein. In the following, a part of the bonding head 14 upper than the copying mechanism 22 is referred to as an “upper part 14u”, and a part of the bonding head 14 lower than the copying mechanism 22 is referred to as a “lower part 14d”.

FIG. 2 is a diagram showing an example of a configuration of the copying mechanism 22. The copying mechanism 22 includes a fixed member 40, a movable member 42 movable with respect to the fixed member 40, and a holder 43. The fixed member 40 and the movable member 42 constitute the spherical aerostatic bearing 44. An upper end of the fixed member 40 is fixed to the upper part 14u of the bonding head 14. A bottom surface of the fixed member 40 is a concave hemispherical surface. In the fixed member 40, an air passage 46 for supplying or sucking air is formed. The air passage 46 penetrates from a side surface of the fixed member 40 to the bottom surface (that is, a concave hemispherical surface). An air pipe 47 (see FIG. 1) for fluidly connecting the air passage 46 and a copying mechanism drive part 32 is connected to the side surface of the fixed member 40.

The movable member 42 is held so as to be three-dimensionally swingable with respect to the fixed member 40. A lower end of the movable member 42 is fixed to the lower part 14d of the bonding head 14, and the movable member 42 is swingable together with the holding surface 20. An upper surface of the movable member 42 is a convex hemispherical surface corresponding to the concave hemispherical surface of the fixed member 40. The holder 43 holds the movable member 42 so as not to interfere with swinging of the movable member 42.

In such a copying mechanism 22, by ejecting compressed air from the concave hemispherical surface of the fixed member 40, the movable member 42 is separated from the fixed member 40 and is supported in a non-contact state. Accordingly, sliding resistance of the movable member 42 is significantly reduced, and it is possible to perform a precise rotational movement with an extremely light force. By stopping the supply of compressed air and vacuum-sucking the movable member 42, the movable member 42 can be fixed in a predetermined posture. In the following, a state in which compressed air is ejected and swinging of the movable member 42 is allowed is referred to as a “free state”, and a state in which the movable member 42 is vacuum-sucked and swinging of the movable member 42 is restricted is referred to as a “locked state”.

Switching of the copying mechanism 22 between the free state and the locked state is performed by the copying mechanism drive part 32. The copying mechanism drive part 32 includes a compressor for supplying compressed air, a vacuum source for vacuum suction, and the like. Driving of the copying mechanism drive part 32 is controlled by the controller 34.

The controller 34 controls driving of each part of the manufacturing apparatus 10. Specifically, the controller 34 drives the movement mechanism 26, or the heater drive part 28, the vacuum source 30 or the like to execute implementation processing for bonding the semiconductor chip 102 to the substrate 100. The controller 34 of this example also executes, prior to the implementation processing, copying processing for making the holding surface 20 copy the mounting surface 18 and thereby adjusting the holding surface 20 and the mounting surface 18 to be parallel. In the following, among the holding surface 20 and the mounting surface 18, the holding surface 20 being a swingable surface is referred to as a “facing surface 50”, and the mounting surface 18 being a fixed surface is referred to as a “reference surface 110”.

Such a controller 34 is a computer including a processor executing various operations and a memory storing data and programs. The controller 34 of this example executes, prior to the implementation processing of the semiconductor chip 102, the copying processing for adjusting the facing surface 50 to be parallel to the reference surface 110. Hereinafter, this copying processing will be described.

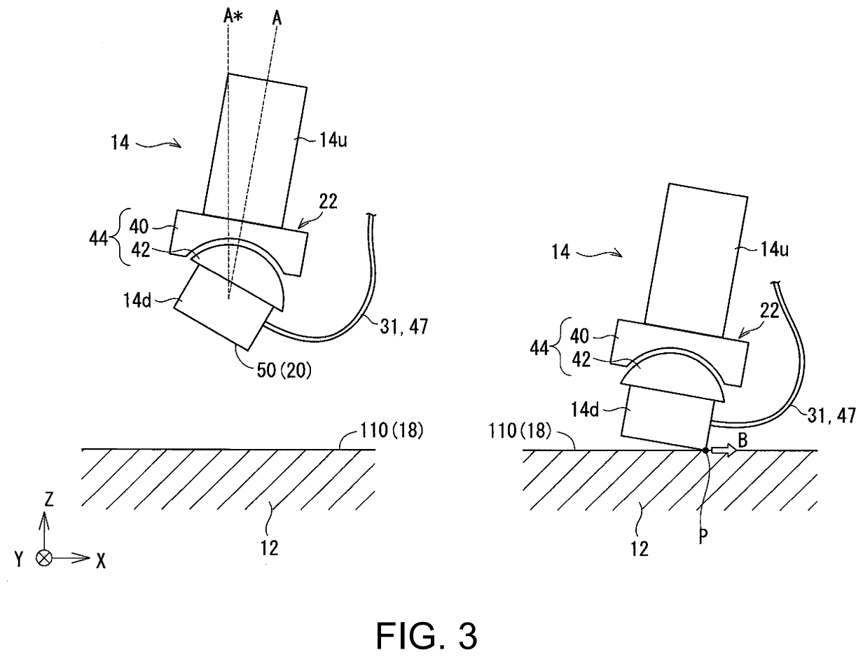

FIG. 3 is a conceptual diagram showing the principles of copying processing. In general, in an apparatus, tilting deviation is present in an axis or a surface. Due to such deviation, the facing surface 50 (holding surface 20) sometimes tilts with respect to the reference surface 110 (mounting surface 18). In the example of FIG. 3, an axis A of the upper part 14u of the bonding head 14 tilts with respect to an ideal axis A*.

In recent years, it has been proposed to use the copying mechanism 22 in order to correct such tilting. Specifically, it has been proposed to perform parallel adjustment on the facing surface 50 by pressing the facing surface 50 against the reference surface 110 after the copying mechanism 22 is set to the free state. In the free state, the movable member 42 can be swung by an extremely small force. Therefore, in theory, if the facing surface 50 is pressed against the reference surface 110, the movable member 42 swings until achieving a state in which the entire facing surface 50 is in contact with the reference surface 110, in other words, a state in which the facing surface 50 is completely parallel to the reference surface 110. At the moment when parallel is achieved, if the copying mechanism 22 is switched to the locked state and swinging of the movable member 42 is restricted, the degree of parallel of the facing surface 50 with respect to the reference surface 110 can be maintained with high accuracy.

However, in reality, tilting of the facing surface 50 cannot be completely eliminated only by causing the facing surface 50 to abut against the reference surface 110, and a parallel offset may remain. In a case where the copying mechanism 22 is locked with the parallel offset remaining, the degree of parallel of the facing surface 50 with respect to the reference surface 110 cannot be maintained with high accuracy.

A reason why such a parallel offset remains is that a force that causes the movable member 42 to swing and frictional force between the facing surface 50 and the reference surface 110 are balanced with each other. That is, when the facing surface 50 is pressed against the reference surface 110, the movable member 42 swings. However, at this time, a contact point P of the facing surface 50 with the reference surface 110 slides in an outward direction (direction of arrow B in FIG. 3) of the bonding head as viewed from the contact point P. The frictional force at this time is a product of the coefficient of friction and the normal force. As the pressing force increases and the normal force increases, the frictional force also increases. That is, at an initial stage when the facing surface 50 is pressed against the reference surface 110, due to small normal force, the contact point P is able to slide on the reference surface 110. However, as the pressing force increases, the frictional force also increases. When this frictional force and the force that causes the movable member 42 to swing are balanced with each other, the movable member 42 stops swinging at that moment. As a result, as shown in the right figure of FIG. 3, tilting of the facing surface 50 with respect to the reference surface 110 sometimes remains.

Here, immediately after the facing surface 50 abuts against the reference surface 110, in the case where the tilting of the facing surface 50 with respect to the reference surface 110 is small, a movement amount of the contact point P required to achieve a completely parallel state is reduced. Hence, in this case, there is a possibility that the facing surface 50 may be able to be completely parallel to the reference surface 110 before the frictional force and the swinging force are balanced with each other. However, generally, an electrical wire or the air pipes 31 and 47 are connected to the movable member 42 and the lower part 14d of the bonding head 14. Hence, in the case where the copying mechanism 22 is set to free while the facing surface 50 and the reference surface 110 are separated from each other, as shown in the left figure of FIG. 3, the movable member 42 is likely to tilt largely in one direction due to the dead weight of the air pipes 31 and 47 or the like, and the tilting of the facing surface 50 with respect to the reference surface 110 is likely to increase. As a result, even if the facing surface 50 is pressed against the reference surface 110 in this state, the frictional force is likely to be balanced with the force that causes the movable member 42 to swing before the completely parallel state is achieved.

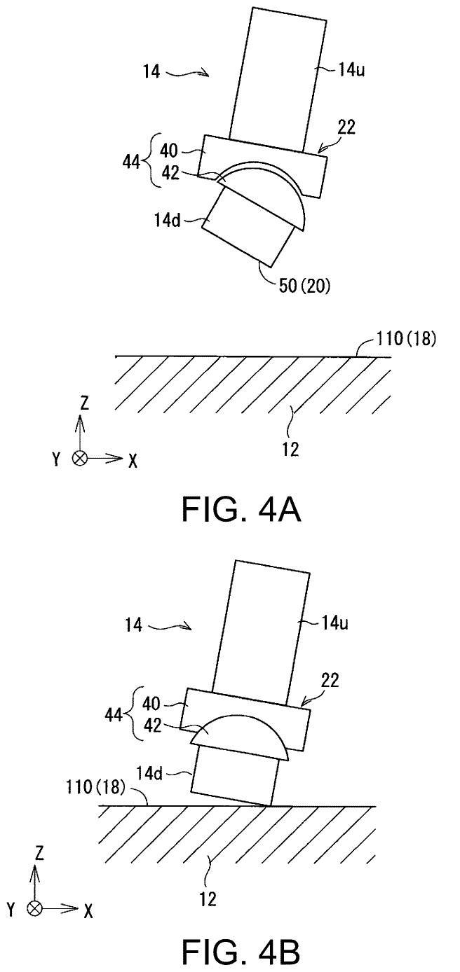

That is, it is difficult to make the facing surface 50 completely parallel to the reference surface 110 simply by pressing the facing surface 50 against the reference surface 110 after the copying mechanism 22 is switched to the free state. Therefore, in this example, the pressing operation of the facing surface 50 against the reference surface 110 is configured to be performed repeatedly. This is described with reference to FIG. 4A to FIG. 6B. FIG. 4A to FIG. 6B are conceptual diagrams showing a state of the copying processing of this example.

The copying processing of this example includes initial processing and adjustment processing. The initial processing is a processing that is executed only once at the beginning of the copying processing. On the other hand, the adjustment processing is a processing that is executed once or multiple times after the initial processing.

The initial processing is almost the same as conventional copying processing. That is, in the initial processing, as shown in FIG. 4A, the copying mechanism 22 is switched to the free state while the facing surface 50 and the reference surface 110 are separated from each other. In this case, the movable member 42 tilts largely to one side due to the dead weight of the air pipe 31 (not shown in FIG. 4A to FIG. 6B) or the like.

In this state, the bonding head 14 is lowered, and the facing surface 50 is pressed against the reference surface 110 with a predetermined load. After that, as shown in FIG. 4B, the copying mechanism 22 is switched from the free state to the locked state. Here, by pressing the facing surface 50 against the reference surface 110 in the free state, the movable member 42 swings to some extent, and the tilting of the facing surface 50 with respect to the reference surface 110 is eliminated to some extent. However, at this moment, the tilting is rarely completely eliminated, and the parallel offset often remains, as shown in FIG. 4B.

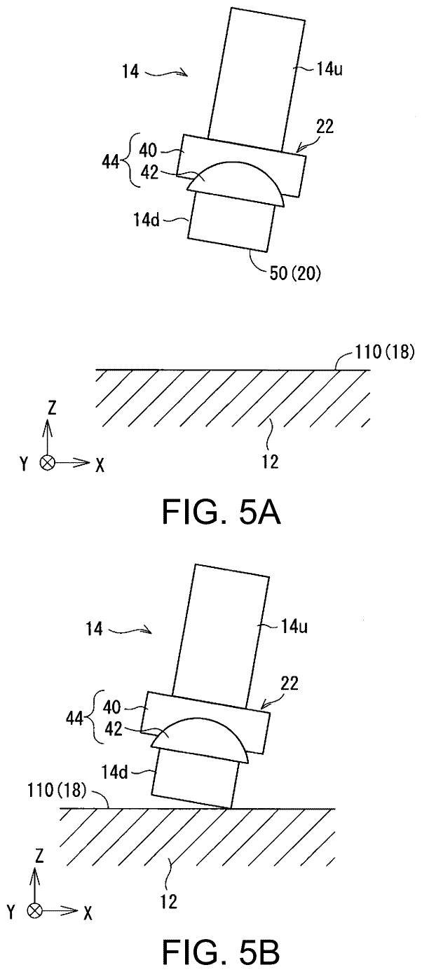

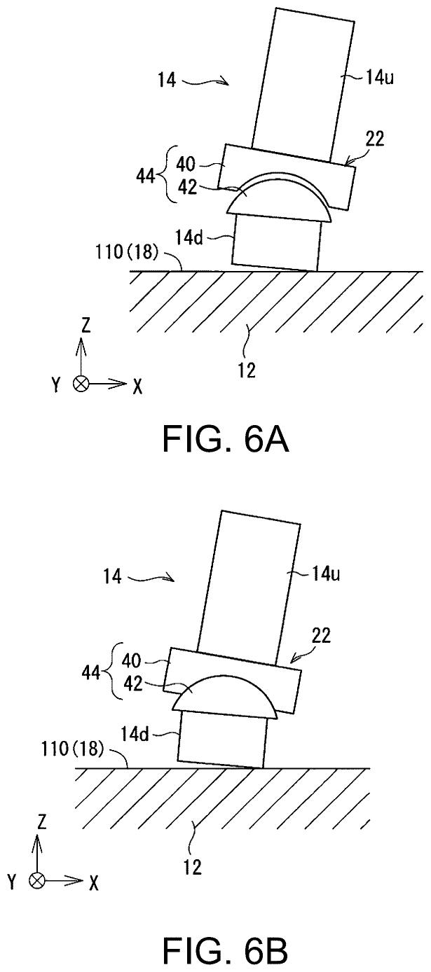

When the above initial processing is completed, the adjustment processing is subsequently executed. In the adjustment processing, the facing surface 50 is pressed against the reference surface 110 while the tilting of the facing surface 50 obtained by the initial processing or the previous adjustment processing is maintained. Specifically, the copying mechanism 22 is in the locked state at the step when the initial processing or the previous adjustment processing is completed. As shown in FIG. 5A, the adjustment processing starts from a state in which the bonding head 14 is once lifted while the locked state is maintained. After that, the bonding head 14 is lowered to cause the facing surface 50 to abut against the reference surface 110, as shown in FIG. 5B. This abutting may be detected based on reaction force from the reference surface 110, or may be detected based on a change in an axial position Pz of the bonding head 14. In any case, if the facing surface 50 abuts against the reference surface 110 in the locked state, the copying mechanism 22 is switched from the locked state to the free state, as shown in FIG. 6A. Then, in this state, the facing surface 50 is pressed against the reference surface 110 with a predetermined load. Accordingly, the movable member 42 swings in a direction of eliminating tilting of the facing surface 50. Then, after this pressing, the copying mechanism 22 is switched from the free state to the locked state.

In the copying processing of this example, the above adjustment processing is executed once or multiple times. Here, as is clear from the foregoing description, in the adjustment processing, the tilting of the facing surface 50 at the start of pressing of the facing surface 50 against the reference surface 110 is maintained to be the tilting of the facing surface 50 obtained by the initial processing or the previous adjustment processing. In other words, in the adjustment processing, when the facing surface 50 is pressed against the reference surface 110, the tilting of the facing surface 50 is already eliminated to some extent. Since the pressing of the facing surface 50 against the reference surface 110 is started in the state in which the tilting of the facing surface 50 is eliminated to some extent, the facing surface 50 is able to be closer to the completely parallel state than in the initial processing or the previous adjustment processing. That is, by executing once or more times the adjustment processing for pressing the facing surface 50 against the reference surface 110 while maintaining the tilting of the facing surface 50 obtained by the initial processing or the previous adjustment processing, the facing surface 50 is able to be relatively reliably parallel to the reference surface 110.

The number of times of execution of the adjustment processing may be specified in advance. Alternatively, the adjustment processing may be repeated until it can be determined that the facing surface 50 is sufficiently parallel to the reference surface 110. The determination that a sufficiently parallel state is achieved may be made based on, for example, a pressing position Pp[i] being the axial position Pz of the bonding head 14 when the facing surface 50 is pressed against the reference surface 110. For example, the axial position Pz when the facing surface 50 is sufficiently parallel can be inferred to some extent from a past measurement or an arrangement of the stage 12 and the bonding head 14. Therefore, the axial position Pz when the facing surface 50 is sufficiently parallel is inferred as a reference position Pdef, and the adjustment processing may be repeated until the pressing position Pp[i] obtained by the actual adjustment processing reaches the reference position Pdef. In the case where the facing surface 50 is sufficiently parallel to the reference surface 110, even if the facing surface 50 is pressed against the reference surface 110, the axial position Pz of the bonding head 14 does not change. Therefore, the adjustment processing may be repeated until a change amount between a pressing position Pp[i−1] obtained by the initial processing or the previous adjustment processing and the pressing position Pp[i] obtained by the current adjustment processing becomes less than the specified reference value. In any case, by executing the adjustment processing once or more times, the facing surface 50 is able to be relatively reliably parallel to the reference surface 110.

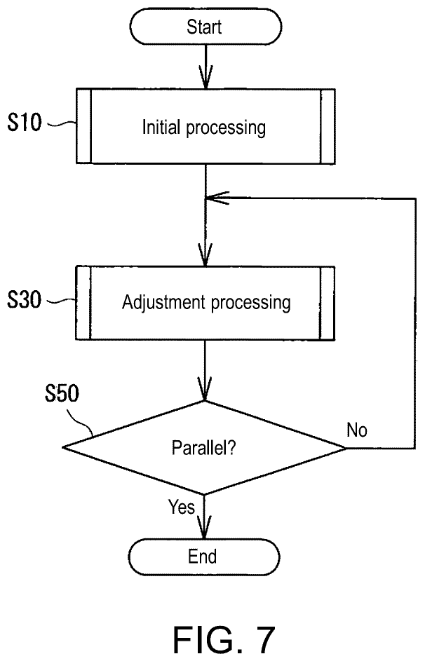

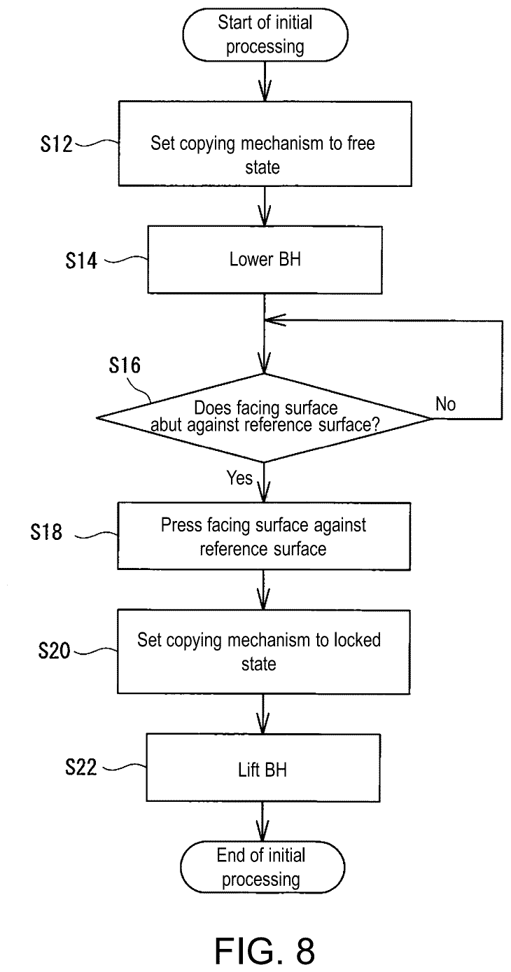

Next, a flow of the copying processing will be described with reference to FIG. 7 to FIG. 9. FIG. 7 is a flowchart describing a flow of the entire copying processing. As described above and as shown in FIG. 7, the controller 34 first executes the initial processing as the copying processing (S10). FIG. 8 is a flowchart showing a flow of the initial processing. In the initial processing, the controller 34 first drives the copying mechanism drive part 32 to set the copying mechanism 22 to the free state (S12). In response to an instruction from the controller 34, the copying mechanism drive part 32 supplies compressed air to the spherical aerostatic bearing 44 to make the movable member 42 swingable. When the free state is achieved, the movable member 42 tilts largely in one direction as shown in FIG. 4A due to dead weight of a pipe or the like. Subsequently, the controller 34 drives the movement mechanism 26 to lower the bonding head 14 toward the stage 12 (S14). The controller 34 monitors whether the facing surface 50 has abutted against the reference surface 110 during this lowering (S16).

When the facing surface 50 abuts against the reference surface 110 as a result of the lowering (Yes in S16), the controller 34 drives the movement mechanism 26 to press the facing surface 50 against the reference surface 110 with a predetermined load (S18). Accordingly, the movable member 42 receives the reaction force from the reference surface 110 and swings in the direction of eliminating tilting. However, as the pressing progresses, the frictional force between the facing surface 50 and the reference surface 110 increases, and is balanced with the force that causes the movable member 42 to swing. In this case, swinging of the movable member 42 is stopped while the tilting of the facing surface 50 with respect to the reference surface 110 remains. The controller 34 stores the axial position Pz of the bonding head 14 at the moment when the pressing operation is completed as the pressing position Pp[i].

If the facing surface 50 can be pressed with the predetermined load, the controller 34 subsequently drives the copying mechanism drive part 32 to switch the copying mechanism 22 to the locked state (S20). Then, if the bonding head 14 is lifted to a height away from the mounting surface 18 (S22), the initial processing is ended.

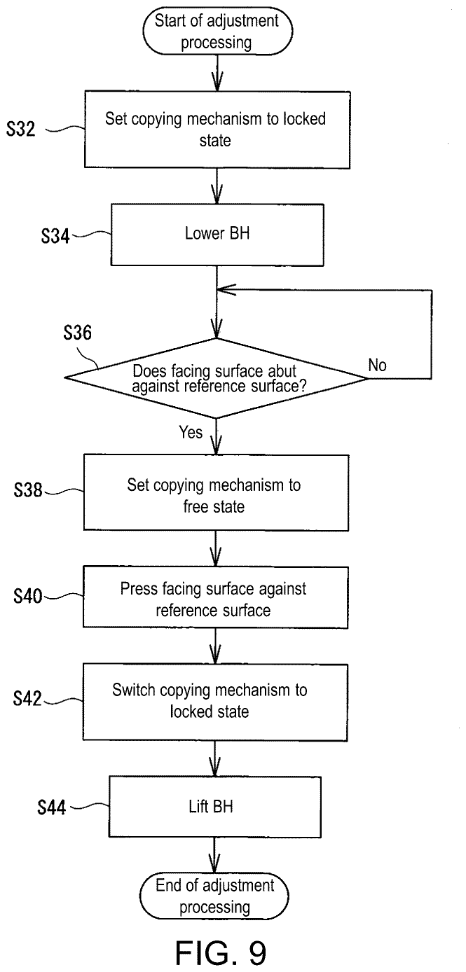

If the initial processing is ended, as shown in FIG. 7, the adjustment processing is subsequently executed (S30). FIG. 9 is a flowchart showing a flow of adjustment processing. At the start of the adjustment processing, the copying mechanism 22 is in the locked state. While maintaining this locked state, the controller 34 drives the movement mechanism 26 to lower the bonding head 14 toward the stage 12 (S32, S34). Since the locked state is maintained, at this moment, the tilting of the facing surface 50 obtained by the initial processing or the previous adjustment processing is maintained. The controller 34 monitors whether the facing surface 50 has abutted against the reference surface 110 during this lowering (S36).

When the facing surface 50 abuts against the reference surface 110 as a result of the lowering (Yes in S36), the controller 34 drives the copying mechanism drive part 32 to switch the copying mechanism 22 from the locked state to the free state (S38). Accordingly, swinging of the movable member 42 is allowed. Here, at this time, since a part of the facing surface 50 has already abutted against the reference surface 110, even if the dead weight of a pipe or the like is provided, the movable member 42 is unable to swing in a direction in which tilting of the facing surface 50 increases. Therefore, tilting of the facing surface 50 immediately after switching to the free state is tilting at the moment when the previous pressing operation is ended.

When the copying mechanism 22 changes to the free state, the controller 34 drives the movement mechanism 26 to press the facing surface 50 against the reference surface 110 with the predetermined load (S40). Accordingly, the movable member 42 receives the reaction force from the reference surface 110 and swings in the direction of eliminating tilting of the facing surface 50. When the completely parallel state is achieved or the frictional force with the reference surface 110 is balanced with the force that causes the movable member 42 to swing, swinging of the movable member 42 is stopped. The controller 34 stores the axial position Pz of the bonding head 14 at the moment when the pressing operation is completed as the pressing position Pp[i].

If the facing surface 50 can be pressed with the predetermined load, the controller 34 subsequently switches the copying mechanism 22 to the locked state (S42). Accordingly, the tilting of the facing surface 50 obtained by the current pressing operation is maintained. Then, if the bonding head 14 is lifted to the height away from the mounting surface 18 (S44), the adjustment processing is ended.

Referring again to FIG. 7, if the adjustment processing is ended, the controller 34 determines whether the facing surface 50 is sufficiently parallel to the reference surface 110 (S50). A method of this confirmation is not particularly limited. Therefore, as described above, the controller 34 may determine that parallel is achieved in the case where the pressing position Pp[i] obtained by an immediately preceding pressing operation reaches the specified reference position Pdef, or may determine that parallel is achieved in the case where when a change amount between the pressing position Pp[i] obtained by the immediately preceding pressing operation and the pressing position Pp[i−1] obtained by the previous pressing operation reaches the specified reference value. In any case, if the controller 34 determines that the facing surface 50 is not sufficiently parallel to the reference surface 110 (No in S50), the controller 34 executes the adjustment processing again. On the other hand, if it is determined that the facing surface 50 is sufficiently parallel to the reference surface 110 (Yes in S50), the copying processing is ended. Here, it is monitored whether parallel is achieved. However, the copying processing may be ended if the number of repetitions of the adjustment processing reaches a predetermined number of times (for example, twice).

As is clear from the above description, in this example, the adjustment processing for performing the current pressing operation is executed once or more times from the state in which the tilting obtained by the previous pressing operation is maintained. As a result, since tilting of the facing surface 50 can be gradually reduced, the facing surface 50 is able to be relatively reliably parallel to the reference surface 110.

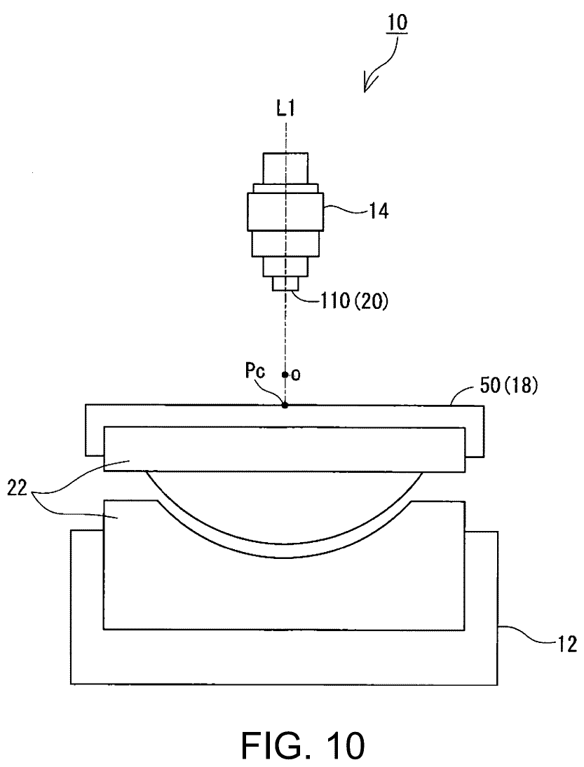

In the above description, the copying mechanism 22 is mounted on the bonding head 14. However, as shown in FIG. 10, the copying mechanism 22 may be provided on the stage 12 rather than the bonding head 14. In this case, the mounting surface 18 of the stage 12 becomes the facing surface 50 that is swingable, and the holding surface 20 of the bonding head 14 becomes the reference surface 110 whose tilting is fixed. Even in this case, the copying processing may be executed in order to make the facing surface 50 (mounting surface 18) parallel to the reference surface 110 (holding surface 20). The procedure of the copying processing in this case is almost the same as the procedure of FIG. 7 to FIG. 9. In the case where the copying mechanism 22 is provided on the stage 12, when the holding surface 20 being the reference surface 110 is pressed against the mounting surface 18, the holding surface 20 is pressed against a position on the mounting surface 18 in the vicinity of an intersection Pc of a normal L1 of the mounting surface 18 passing through a swing center O of the copying mechanism 22 and the mounting surface 18.

In the foregoing description, the facing surface 50 is directly pressed against the reference surface 110. However, the facing surface 50 may be indirectly pressed against the reference surface 110. For example, in the case where the bonding head 14 is equipped with the copying mechanism 22, a chip member may be held by the holding surface 20 being the facing surface 50, and the chip member may be pressed against the reference surface 110. In this case, the substrate 100 is supported by the mounting surface 18 being the reference surface 110, and the facing surface 50 or the chip member held by the facing surface 50 may be pressed against the substrate 100.

In the foregoing description, the initial processing is executed before the adjustment processing. However, the initial processing may be omitted. That is, it is possible to only execute the processing of FIG. 9 once or more times without performing the processing of FIG. 8. In the foregoing description, the facing surface 50 abuts against or is pressed against the reference surface 110 by movement of the bonding head 14. However, it is possible to move the stage 12 rather than or in addition to the bonding head 14.

What is claimed is:

1. A manufacturing method of a semiconductor device, manufacturing a semiconductor device by bonding a chip sucked and held by a holding surface of a bonding head having a copying mechanism to a substrate mounted on a stage, the manufacturing method of a semiconductor device comprising:
equipping the stage or the bonding head with the copying mechanism, the copying mechanism having a first spherical surface and a second spherical surface provided swingably with respect to the first spherical surface, the copying mechanism causing a facing surface being the mounting surface or the holding surface to swing with respect to a reference surface facing the facing surface and being the holding surface or the mounting surface, wherein the copying mechanism is switchable between a free state in which swinging of the facing surface is enabled and a locked state in which swinging of the facing surface is restricted;
performing an adjustment step comprising: causing the facing surface to directly or indirectly abut against the reference surface while the copying mechanism is in the locked state, then switching the copying mechanism to the free state and directly or indirectly pressing the facing surface against the reference surface, and switching the copying mechanism to the locked state; and
performing the adjustment step once or more times and adjusting the facing surface to be parallel to the reference surface.

2. The manufacturing method of a semiconductor device according to claim 1, further comprising:
repeating the adjustment step until a pressing position being an axial position of the bonding head when the facing surface is pressed against the reference surface in the adjustment step reaches a specified reference value.

3. The manufacturing method of a semiconductor device according to claim 1, further comprising:
storing an axial position of the bonding head when the facing surface is pressed against the reference surface as a pressing position; and
repeating the adjustment step until a change amount between the pressing position obtained by a previous pressing and the pressing position obtained by a current pressing reaches a specified reference value.

4. The manufacturing method of a semiconductor device according to claim 1, further comprising:
mounting the copying mechanism on the stage; and
pressing the holding surface being the reference surface against an intersection of the mounting surface being the facing surface and a normal of the mounting surface passing through a swing center of the copying mechanism in the adjustment step.

5. The manufacturing method of a semiconductor device according to claim 1, further comprising:
executing an initial step prior to the adjustment step; and
causing the facing surface to directly or indirectly abut against the reference surface after setting the copying mechanism to the free state, then directly or indirectly pressing the facing surface against the reference surface, and then switching the copying mechanism to the locked state in the initial step.
